(19) United States
(12) Patent Application Publication
(10) Pub. No.: US 2005/0000565 A1
(43) Pub. Date: Jan. 6, 2005

(54) Self-assembly methods for the fabrication of McFarland-Tang photovoltaic devices

(76) Inventor: Tingying Zeng, Blacksburg, VA (US)

Correspondence Address: McGuire Woods LLP, Suite 1800, 1750 Tysons Blvd., McLean, VA, 22102, US

(21) Appl. No.: 10/849,903

(22) Filed: May 21, 2004

Related U.S. Application Data
(60) Provisional application No. 60/472,580, filed on May 22, 2003.

(51) Int. Cl. H01L 31/00; H01L 21/302

(52) U.S. Cl. 136/256; 136/264; 438/689

(57) ABSTRACT

The present invention relates to self-assembly methodologies, such as electrostatic self-assembly, layer by layer covalent self-assembly, nuclear induced self-assembly, regular ink jet printing and self-assembly inkjet printing methodologies for the fabrication of McFarland-Tang multilayer structured photovoltaic devices, photo-detectors and sensors. The methodology of the present invention allows for the flexibility to nanofabricate the thin layer of the semiconductor layer, the ultra-thin noble metal layer, and the ultra-thin photosensitizer layers to form the desired multilayer photovoltaic devices. Extending the self-assembly processes by ink-jet printing allows for the up-scaled nano-manufacture of McFarland-Tang photovoltaic devices on any type of substrate, including light-weight flexible photovoltaic fabrics and paper.

### CROSS-REFERENCE TO RELATED APPLICATIONS

The present invention is related to and claims the benefit of provisional patent application Ser. No. 60/472,580, filed May 22, 2003, which is expressly incorporated fully herein by reference in its entirety.

### STATEMENT REGARDING FEDERALLY SPONSORED RESEARCH

This invention was made in connection with Government support under Contract number NS2-3175 awarded by the National Science Foundation. The Government has certain rights in the invention.

### FIELD OF THE INVENTION

This invention concerns the fabrication of McFarland-Tang photovoltaic (PV) devices using self-assembly process, such as dipping methods, self-assembly inkjet printing and regular ink jet printing methods.

### BACKGROUND OF THE INVENTION

Recent advances in technology have increased the demand for improved material processing with strict tolerances on processing parameters. For example, current integrated circuit technology already requires tolerances on processing dimensions on a submicron scale. Self-assembly approaches have been developed for the fabrication of very thin film materials. These self-assembly processes, however, while highly advantageous, generally are limited with respect to the types of materials that can be deposited by a particular process, by costs and manufacturing facilities.

Presently, film materials are manufactured in large manufacturing facilities that are expensive to build and to operate. For example, semiconductor device fabrication generally requires specialized microlithography and chemical etching equipment as well as extensive measures to avoid process contamination. Furthermore, the fabrication processes typically used to create electronic and electromechanical components involve harsh conditions, such as high temperatures and/or caustic chemicals. In addition, high temperatures also preclude fabrication on substrates such as flexible plastics, which offer widespread availability and lower costs. Furthermore, the thickness and other properties of films manufactured by these traditional methods are not uniform.

### SUMMARY OF THE INVENTION

The present invention is directed to the molecular self-assembly processes for the nano-fabrication of the molecularly uniform thin film McFarland-Tang solar cells and relative photovoltaic devices on any type of substrate. The present invention is directed to methods, such a dipping processes, coating, and printing for the fabrication of McFarland-Tang solar cells and the relevant photovoltaic devices on any kinds of substrates.

One aspect of the present invention relates to a method of manufacturing a McFarland-Tang photovoltaic device comprising providing an electrode layer on a substrate; depositing a wide bandgap semiconductor layer onto the electrode layer; depositing a noble metal layer onto the wide bandgap semiconductor layer; and depositing a photosensitizing layer onto the noble metal layer, where at least one of the layers is fabricated by self-assembly.

Another aspect of the present invention is directed to a McFarland-Tang photovoltaic (PV) device built on a substrate comprising an electrode, a wide bandgap layer, a noble metal layer, and a photosensitizing layer wherein at least one of the wide bandgap layer, the noble metal layer and the photosensitizing layer is fabricated by self-assembly.

A further aspect of the present invention is related to a McFarland-Tang PV device comprising an InP Q-dot layer having a thickness of about 80 nm, a gold layer having a thickness of about 100 nm, and a TiO₂ layer having a thickness of about 200 nm, wherein at least one of the layers has been fabricated by self-assembly.

An even further aspect of the present invention is related to a McFarland-Tang PV device comprising an InP Q-dot layer having a thickness of about 80 nm, a gold layer having a thickness of about 30 nm, and a TiO₂ layer having a thickness of about 100 nm, wherein at least one of the layers has been fabricated by self-assembly.

### BRIEF DESCRIPTION OF THE FIGURES

FIG. 1 is a diagram of the sandwich-layered structure of the inkjet printed sensitized semiconductor Q-dot PV cell on a number of substrates.

FIG. 2 is a diagram schematic of electron-transfer processes occurring in the self-assembled dye or other sensitizing semiconductor Q-dot McFarland-Tang solar cells. inj=injection; reg=regeneration; and φ is the Schottky Barrier that is formed between the interface of gold and TiO₂.

FIG. 3 illustrates an embodiment of the present invention.

FIG. 4 illustrates an alternative embodiment of the present invention.

FIG. 5 represents PV performance of a McFarland-Tang solar cell.

FIG. 6 is illustrating the optical absorbance of the InP Q-dot solution.

FIG. 7 is illustrating the PV response of a self-assembled McFarland-Tang solar cell.

### DETAILED DESCRIPTION OF EMBODIMENTS OF THE INVENTION

It is understood that the present invention is not limited to the particular methodology, protocols, devices, apparatus, materials, and reagents, etc., described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include plural reference unless the context clearly dictates otherwise. Thus, for example, a reference to “a nanoparticle” is a reference to one or more nanoparticles and equivalents thereof known to those skilled in the art and so forth.

The present invention is generally directed to the fabrication of McFarland-Tang photovoltaic devices by using self-assembly methodologies. It is contemplated that the self-assembly methodologies include the electrostatic self assembly (ESA) process, the covalent chemical bonding layer-by-layer self assembly (CSA LbL) process, and the nuclear induced self assembly (NISA) process. Additionally, the self-assembly methods of the present invention may be extended to fabricate related photovoltaic devices, such as photodetectors, on any type of substrate. As will be discussed in more detail below, the self-assembly method may be performed using a variety of techniques, such as dipping processes, coating, and printing. In one embodiment, printing methodologies may include inkjet printing.

The self-assembly methods of the present invention may offer the advantages of (i) fabricating films through molecular layer by layer deposition or through controlling reaction concentration and time to more precisely control film thickness, (ii) greater ease of nano-manufacturing multilayer sandwich-structured nanodevices, (iii) significantly improving the interface interaction and the internal nanostructure of the molecular level photovoltaic film thereby achieving high-efficient charge transfer which may result in high incident photon-to-electrical current conversion efficiency (IPCE), and (iv) fabricating the packaging layer directly on the devices.

The present invention is generally directed to self-assembly methodologies for fabricating McFarland-Tang solar cells. Typically, McFarland-Tang solar cells avoid the use of hole transport materials that are generally used in Grätzel solar cells. In principle, with conventional solid-state solar cells, such as Grätzel solar cells, photon-induced electron hole pairs are created by light absorption in a semiconductor, with charge separation and collection accomplished under influence of electric fields within the semiconductor. The fabrication of Grätzel-type solid solar cells and relative photovoltaic devices by self-assembly methods has been described in U.S. patent application Ser. No. 10/684,594, which is expressly incorporated fully herein by reference in its entirety.

In McFarland-Tang solar cells, however, photon absorption occurs in photosensitizers deposited on the surface of an ultra-thin metal semiconductor junction Schottky diode. Hence, the photo-excited electrons are transferred to the metal and travel ballistically to and over the Schottky barrier thereby providing the photocurrent output. Low energy (about 1 eV) electrons have long, ballistic path lengths in noble metals, allowing a large fraction of the electrons to be collected. Typically in McFarland-Tang photovoltaic devices, the photosensitizer may be regenerated by the transfer of thermalized electrons from state near E_{f} in the adjacent metal naturally; however, the semiconductor serves only for majority charge transport and separation.

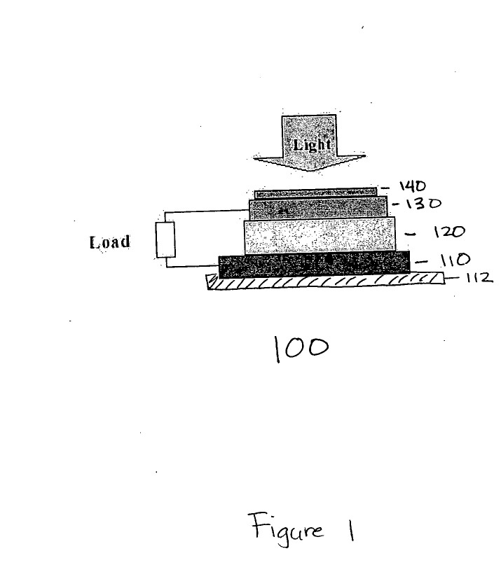

Now referring to FIG. 1, an embodiment of the present invention illustrating a multilayer sandwich-structured McFarland-Tang photovoltaic device is shown. The McFarland-Tang photovoltaic device is generally depicted as reference numeral 100 and includes a substrate 112, an electrode 110, a wide-band gap semiconductor layer 120, a thin layer proper metal film 130, and a thin layer photosensitizer 140.

The self-assembly methods of the present invention may allow for the fabrication of the thin layer of the semiconductor layer 120, the ultra-thin noble metal layer 130 and the ultra-thin photosensitizer layers 140 to form the desired multilayer photovoltaic devices as shown in FIG. 1. Moreover, the self assembly processes by ink jet printing allows the up-scaled nano-manufacture of this McFarland-Tang solar cells on any kind of substrate, including light-weight flexible substrates to form photovoltaic fabrics and papers, for example.

In one embodiment, the electrode 110 may be metal, such as indium-tin-oxide film, Ti, Pt, Ag, Au, or any other suitable conductive film that would act as an electrode for a photovoltaic device on a substrate. Suitable substrates contemplated by the present invention may be a glass slide, single crystal silicon, polycarbonate, kapton, polyethylene rigid polymer materials, flexible polymer materials, ceramics, metal surfaces, etched surfaces, functionalized surfaces, and non-functionalized surfaces, or any flexible, free-standing film or other suitable electrode substrates known by those of ordinary skill in the art. In implementation, it is contemplated that the conductive substrates match the energy level of the electrode in order to collect the charge. The photovoltaic device may be illuminated from the transparent substrate side or from the photoreceptor side, which may not require the use of transparent substrates.

The wide-band gap semiconductor layer 120 may be fabricated from any suitable wide band-gap n-type semiconductors, such as TiO₂, SnO_{2l, WO}₃, ZnO, Nb₂O₅, Ta₂O₃, and any other wide band-gap n-type semiconductor known by one of ordinary skill in the art. Moreover, in one implementation, the semiconductor particles may be sized on the order of nanoparticles. The size of the nanoparticles used by the present invention may be in a range of about 1 nm to about 1000 nm. Specifically, the size of the nanoparticle may be in the range of about 1 nm to about 100 nm. The nanoparticles may be uniformly or spatially dispersed through the self-assembled film.

In one embodiment, wide bandgap semiconductor nanoparticles may be used to achieve quantum effects both in size to tune the bandgap and the Shottky Barrier and the interface between the noble metal 130 and the semiconductor layer 120. Further, it is contemplated that energy level favorite core-shell nanostructured semiconductor be attained, such as TiO₂ core-SnO₂ shell, WO₃ core-SnO₂ shell which may enhance the ability for electron collection and charge transfer. In one embodiment, the semiconductor layer may have a thickness in the range of about 5 nm to about 1000 nm.

The thin layer proper metal film 130 may be fabricated from any suitable noble metal such as Pt, Au, Pd, Ag, Ru, and any other suitable noble metal known by one skilled in the art. In implementation, the noble metals may provide the favorite Schottky barrier to allow the photon-induced electron transfer to the semiconductor layer 140 for collection. In one embodiment, it is contemplated that the noble metal layer may have a thickness in the range of about 10 nm to about 250 nm.

The thin layer photosensitizer layer 140 may be generally fabricated from dyes used in Grätzel solar cells and sensitizing semiconductor quantum dots of IIB-VIA and IIIA-VI group compounds. It is contemplated by the present invention, that the photosensitizers may include organic dyes which have excited energy level higher than the Schottky barrier formed between the noble metal and the wide bandgap semiconductor interface. The dyes may be chosen by cyclic voltammetry and may include all types of natural dyes, artificial dyes, and ruthenium complexes. For example, the natural dyes may comprise as the main components, cyanin 3-glycoside and cyanin 3-rutinoside, multi-chromophoric perylene derivatives, derivatives of phthalocyanine and porphyrin, and derivatives of alizarin, which may be extracted from blackberry juice. Ruthenium complex dyes may include polypyridyl complexes, and modified ruthenium complexes, such as black dye, and other dyes which shift to IR range excitation.

In an alternate embodiment of the invention, inorganic semiconductors may be used as the sensitizing photosensitizers. In the embodiment, the sensitizing semiconductors may be prepared from the elements of group IIB, VIA, IIIA, and VA, for example. In particular, the sensitizing semiconductors may be in the form of Q-dots or nanocrystals. Suitable sensitizing Q-dots may include PbS, ZnS, CdS, CdSe, CdTe, HgTe, HgSe, PbSe, InAs, InP, GaAs, InSb, InAsP, GaAsP, and any other suitable components known by those skilled in the art.

It is further contemplated that the core-shell nano-structured semiconductor nanocrystals of the above described components, including Type I and Type II, may be used as the photosensitizers in this invention. Since the light absorption needed to excite the mid-bandgap Q-dots such as GaAs and InP, and the narrow bandgap materials such as InSb and HgTe, are in the IR range, these components may be implemented for the design of solar cells and photovoltaic devices that operate in the IR range, as well as in the development of IR photovoltaic detectors for the use in Space. In one embodiment of the present invention, the photosensitizer layer may have a thickness in the range of about 1 nm to about 1000 nm. In a specific embodiment, the photosensitizer layer may have a thickness of about 1 nm to about 500 nm.

The methodologies known by one skilled in the art for producing macro-dyes by bioprocessing and environmentally friendly processing may be used as the photosensitizer sources in the present invention. Moreover, dye cocktail methodologies to produce the photosensitizer-dye inks for ESA inkjet printing on ultrathin noble metal films are also contemplated. The dye ink may be in the form of mixtures of porphyrins and phthalocyanines, as well as ruthenium complexes and the natural dye cyanins. Optimization of the best components leads to high performance solar cells produced through the efficient use of sunlight in this invention. Long-chain porphyrins and phthalocyanines have strong absorptions in the IR region, which may allow the PV cells to extend the photoexcitation light sources, thereby resulting in a high-enhanced absorption to sunlight. Panchromatic sensitization extending throughout the visible and near-IR regions is a typical characteristic for the cell performance improvement as well in this invention.

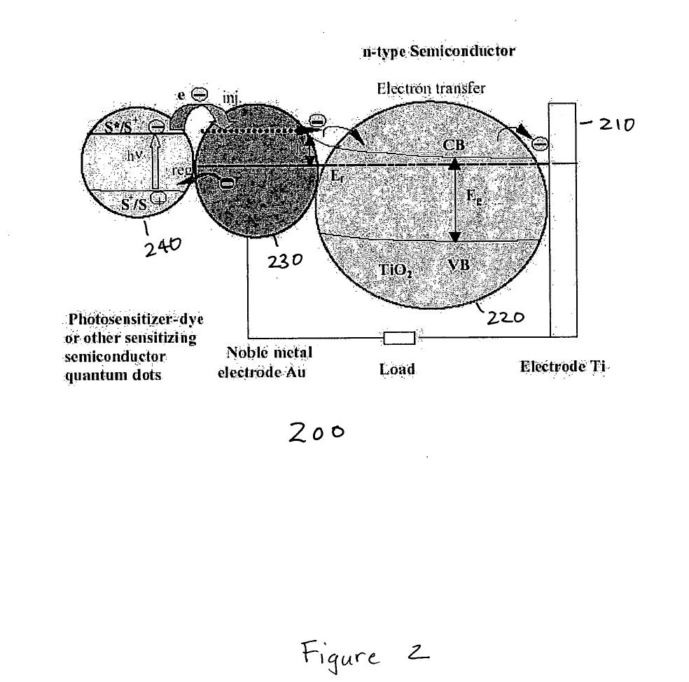

FIG. 2 shows a detailed view of the electron-transfer process occurring within the self-assembled dye or other sensitizing semiconductor Q-dot sensitized McFarland-Tang solar cell. The McFarland-Tang photovoltaic device, generally depicted as reference numeral 200, includes the electrode 210, the wide bandgap layer 220, the noble metal layer 230, and the photosensitizing Q-dot layer 240. In this embodiment, the Shottky barrier is formed between the interface of gold 230 and TiO₂ wide bandgap layer 220. The photosensitizers and the energy levels are the approximate relative positions of potentials and band energies of the different components.

The present invention may also include self-assembly methods for the deposition of the various components of a McFarland-Tang photovoltaic device. Specifically, the present invention may include methods for fabrication of the thin layer semiconductor layer, the ultra-thin noble metal layer and the ultra-thin photosensitizer layers to form the desired multilayer photovoltaic devices as shown in FIG. 1.

One particular embodiment of the present invention is directed to self-assembly printing methods. “Printing” may include all forms of printing and coating, including, but without limitation: pre-metered coatings such as patch die coating, slot or extrusion coating, slide or cascade coating, and curtain coating; roll coating such as knife over roll coating, forward and reverse roll coating; gravure coating; dip coating; spray coating; meniscus coating; spin coating; brush coating; air knife coating; silk screen printing processes; electrostatic printing processes; thermal printing processes; ink jet printing processes; and other similar techniques. Thus, the resulting films of the present invention may be flexible.

It is contemplated that the self-assembly methods include the layer-by-layer electrostatic self-assembly processes (ESA), and any other modified molecular self-assemblies, such as layer-by-layer covalent self-assembly (LbL CSA), and nuclear-induced molecular self-assembly (NISA) processes. These self-assembly processes may form two-dimensional (2D) and three-dimensional (3D) self-assembled nanostructured photoactive films. In another embodiment, the present invention is directed to both regular inkjet printing and self-assembly (SA)-inkjet printing. The self-assembly methodologies of the present invention have been described in U.S. patent application Ser. No. 10/774,683, which is expressly incorporated fully herein by reference in its entirety.

Generally, the ink jet printing methods of the present invention may be used to print thin film on any type of substrate. It is contemplated that the substrate choice depends upon the specific application of the McFarland-Tang photovoltaic device and may vary for different environments. Moreover, the substrates may require the use of chemical or physical methods to modify the surface before ink jet printing the first conductive coating layer onto the substrate. The substrates may include rigid and flexible substrates, such as ITO-coated glass, any window material, plastics materials, Kapton, fabrics, tents, papers and any other substrates known by those skilled in the art.

It is further contemplated that conductive substrates may be used for the direct printing after the substrates have been cleaned. The electrode coating may be any conductive material known to those of skill in the art. In one embodiment, printed “ink” sols such as indium tin oxide, gold nanoclusters, platinum nanoparticle sol, and silver sols may be used as the electrode coating. Additionally, high conductive polymer or carbon nanotubes may be printed as the electrode.

In the present invention, the standard self-assembly dipping methods may be directly extended to inkjet printing. The dipping process, however, may require certain modifications which take into consideration that (i) the substrate needs to be handled by the ink jet printer (i.e., the printer may invert and curve the substrate during printing) and (ii) exact volumes of precursor materials must be delivered to the substrate surface by the ink delivery system.

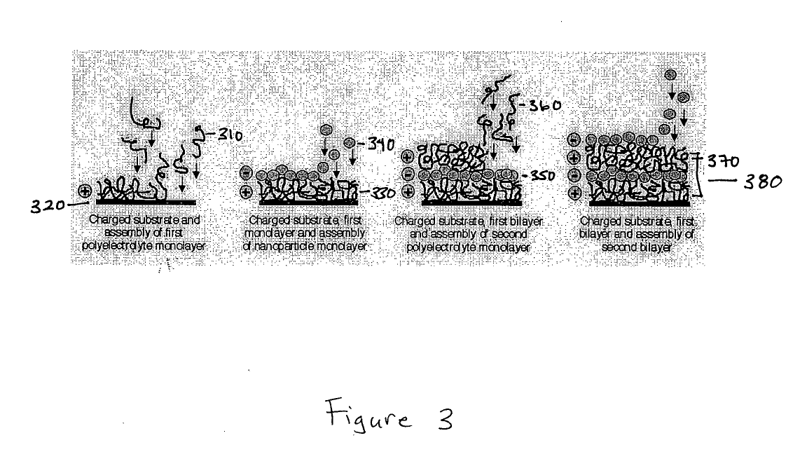

The ESA methodology of the present invention may allow for the patterning of McFarland-Tang photovoltaic device arrays on both rigid and flexible substrate materials. FIG. 3, which represents an embodiment of the present invention, generally illustrates the ESA self-assembly methodology of the present invention. This embodiment involves the layer-by-layer formation of thin films from aqueous solutions of semiconductor nanoclusters and selected polymers. In this embodiment, a first polyelectrolyte 310 is deposited onto a charged substrate 320 to form the first polyelectrolyte monolayer 330. Subsequently, a nanoparticle 340 having a charge opposite of the first polyelectrolyte layer 330 is deposited onto the polyelectrolyte layer 330 to form a first nanoparticle layer 350. Following, a second polyelectrolyte 360 is deposited onto nanoparticle layer 350 to form a second polyelectrolyte layer 370 and thereby forming a first bilayer 380. In this embodiment, the layer-by-layer self assembly process through electrostatic bonding may be repeated until the desired film thickness is achieved.

The ESA methodology of the present invention allows for control over the thickness uniformity at the molecular level, morphology within each deposited layer or set of layers, and dispersion uniformity of molecules within each segment of the device. In order to protect the device from moisture, oxygen, or other damage, a sealing or protective coating may be applied with the printing process during fabrication. It is contemplated that integration of these steps may greatly increase the lifetime of the product.

Another embodiment of the present invention is directed to the LbL CSA methodology for the fabrication of McFarland-Tang photovoltaic device arrays on both rigid and flexible substrate materials. It is contemplated that the layers fabricated by LbL CSA may be composed of nanoparticles and molecular crosslinkers. In this embodiment, the molecular crosslinkers may act as nanoparticle binders in a layer-by-layer self-assembly fashion. The cohesive multicomponent films result from the inherent attractive interaction between the nanoparticles and the crosslinking molecules that are covalent by design.

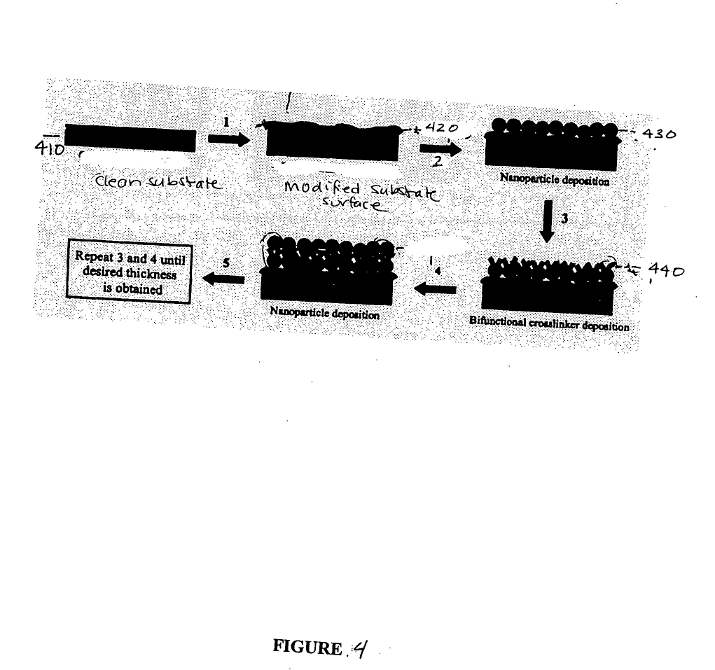

FIG. 4, which represents an embodiment of the present invention, generally depicts the LbL CSA methodology. In this embodiment, the substrate 410 is cleaned and may be modified with an appropriate precursor 420, such as an adhesion promoting agent. The precursor may comprise an organic functional molecule whose terminal groups may bind to the nanoparticle of interest, such as organosilane. A nanoparticle may then be deposited onto the modified substrate to form a nanoparticle layer 420. Following, a crosslinker may be deposited onto the nanoparticle layer 420 to form a crosslinker layer 440. The crosslinker molecules chemically bind to the nanoparticle surface on one end and leave behind the other for a subsequent layer of nanoparticles to absorb. The process of forming alternating layers of nanoparticles and crosslinkers may be repeated until the desired film thickness is achieved.

The term “nanoparticle” refers to a particle, generally metallic, semiconducting, magnetic, ceramic and dielectric, having a diameter in the range of about 1 nm to about 1000 nm. Specifically, the nanoparticle may have a diameter in the range of about 1 nm to about 100 nm. The nanoparticles may be functionalized and/or naked on the particle surface. The nanoparticles may be dispersed uniformly or spatially patterned through the self-assembled film.

The term “semiconductor nanoparticle” refers to a nanoparticle as defined above that is composed of an inorganic semiconductive material, an alloy or other mixture of inorganic semiconductive materials.

The term “metallic nanoparticle” refers to a nanoparticle as defined above that is composed of a metallic material, an alloy or other mixture of metallic materials, or a metallic core contained within one or more metallic overcoat layers.

The crosslinkers are molecules that may comprise at least one functional group that is capable of covalently or noncovalently binding to the desired molecule, such as the nanoparticle or precursor. Additionally, the crosslinker may contain a frame that is capable of supporting the functional group. The crosslinker provides bonding capabilities that may lead to the formation of complexes. The crosslinker may include more than two functional groups. The frame of the linker supporting the functional group may be inorganic or organic. The frame may comprise thio and/or mercapto moieties, linear or branched carbon chains, cyclical carbon moieties, saturated carbon moieties, unsaturated carbon moieties, aromatic carbon units, halogenated carbon groups and combinations thereof. Additionally, the structure of the linker may be selected to yield desirable properties of the film. For example, the size of the linker may be a control parameter that may affect the periodicity of the film and self-organization properties. Convenient linkers include functionalized organic molecules. The crosslinkers of the present invention may comprise one or more functional groups comprising hydroxyl groups, amino groups, carboxyl groups, carboxylic acid anhydride groups, mercapto groups, and hydrosilicon groups.

Thickness of the self-assembled film may be controlled through the number of bilayers deposited and the size of nanoparticles. The conductivity and the optical transparency may be simultaneously manipulated (inversely related) through the chain length of the molecular crosslinkers between gold nanoparticles. For example, the shorter the effective molecular chain length, the better the conductivity of the film. These molecular bridges function as tiny circuit wires that allow for electron transport once the percolation threshold is attained. Conjugated chains may enhance this electron transporting property.

In a further embodiment, the present invention is directed to a NISA methodology for the fabrication of McFarland-Tang photovoltaic device arrays on both rigid and flexible substrate materials. Generally, NISA involves providing a substrate that has a primary layer, which may comprise organic functional molecules or nanoparticles, and immersing this layer into a nanoparticle growth solution. The growth solution may comprise a metal that corresponds to the nanoparticle in the primary layer and a reducing agent. The reducing agent reduces the metal onto the surface of the primary layer of nanoparticles. Using this methodology, electrically conductive gold films on flexible and rigid polymer materials, may be constructed. In this embodiment, the film thickness may be controlled by adjusting the reaction time and concentration of the reaction mixture.

The self-assembly methods of the present invention have a number of advantages over traditional thin-film synthesis methods for the fabrication of McFarland-Tang type devices. For example, the self-assembly methods may allow for the fabrication of nanoscale, layer-by-layer composite films of metallopolydye complexes and semiconductor nanocrystals that are uniform at the molecular level. The nano-structured film may result in very high efficiency photo-induced electron transfer from excited dye molecules to semiconductor nanoparticles when illuminated by light of the proper wavelength, as illustrated in FIG. 2.

In implementation, the semiconductor nanocrystals may be self-assembled from ionic transition-metal poly-dye complexes (macrodye polymer molecules) into multilayered thin films where the thickness and nanostructure are precisely controlled by the self-assembly methods of the present invention by controlling the number of deposited bilayers. This provides for excellent contact between the photosensitizer polydyes and the semiconductor nanocrystals, resulting in high injection of the photo-induced electrons from dye molecules to the semiconductor nanoparticles. The semiconductor nanocrystals may provide quantum size effects both in bandgap and in volume. The small volume effect may provide for the high charge transfer on the particle surface, resulting in the high efficiency collection of photo-induced electrons on the electrodes. Thus, the recapture of the electrons by the positively charged dye molecules will be greatly decreased and an efficient charge separation in the system may be realized.

The invention has been disclosed broadly and illustrated in reference to representative embodiments described above. Those skilled in the art will recognize that various modifications can be made to the present invention without departing from the spirit and scope thereof.

Without further elaboration, it is believed that one skilled in the art, using the preceding description, can utilize the present invention to the fullest extent. The following examples are illustrative only, and not limiting of the remainder of the disclosure in any way whatsoever.

### EXAMPLES

### Example 1

### InP Q-Dot Sensitized Au/TiO₂/Ti on a Silicon Substrate McFarland-Tang Solar Cell

In this example a McFarland-Tang solar cell built on a silicon substrate is described. In this device, a Ti layer was deposited on a silicon substrate using a vacuum deposition method in a thickness of about 50 nm. A TiO₂ anatase thin film was self-assembled using the layer-by-layer ESA methodology of the present invention using a 15 nm TiO₂ anatase as the nanoparticle and 3-MPS (3-mercapto-1-propanesulfonic acid sodium salt) as the polyelectrolyte. A 30 nm Au film was then self-assembled on the TiO₂ layer by the NISA method of the present invention using HAuCl₄ as the gold source and NaHB₄ as the reduction agent. A monolayer of bi-functional thiol molecules was used to modify the surface of the Au film to enhance the up taking of the InP Q-dots. A solar simulator was used as the light source to illuminate the device from the InP Q-dot film side.

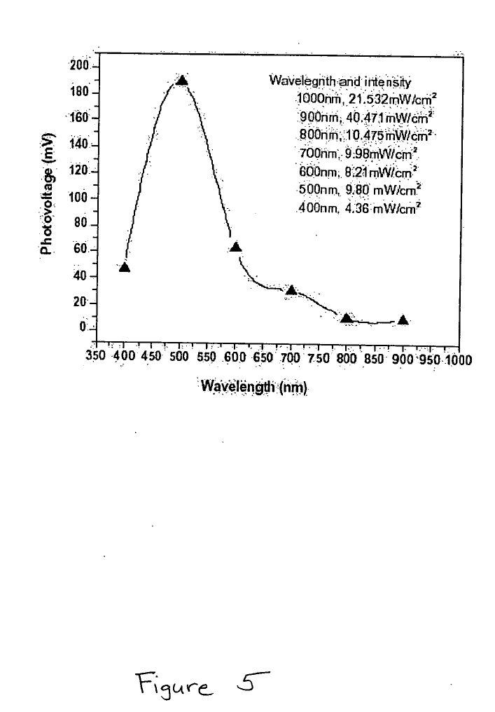

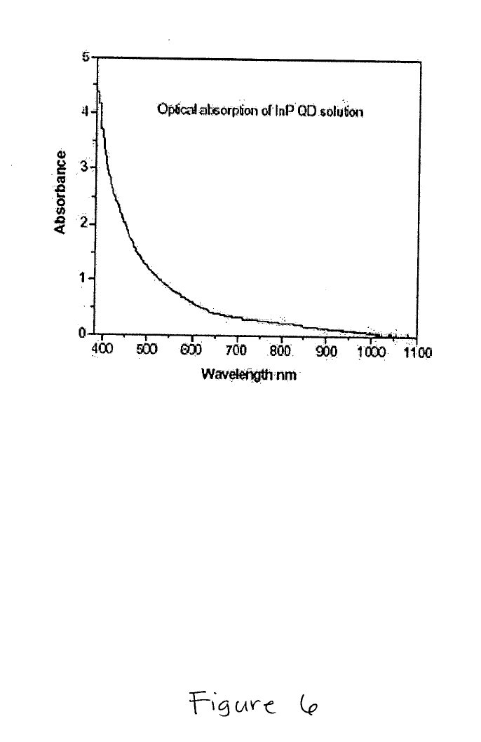

Tuning the Q-dot particle size resulted in a PV response that varied with illuminating light wavelength from the range of about 400 nm to about 900 nm using a solar simulator. FIG. 5 is a represents PV performance using larger particle InP Q-dots as the photosensitizers to build the McFarland-Tang solar cell. The InP Q-dot solution has an optical absorption ranging from about 380 nm to about 900 nm (FIG. 6).

The McFarland-Tang solar cell in this example showed a short circuit current of about 36 μA/cm² and a maximum open circuit photovoltage of about 188 mV under the illumination of a 500 nm light with an intensity of 9.8 mW/cm².

### Example 2

### Change in Thickness of Components Results in Different PV Response

A self-assembled McFarland-Tang solar cell built on a silicon substrate is described in this example. In this device, a Ti layer was deposited on a silicon substrate using a vacuum deposition method to a thickness of about 150 m and used as the electrode. A TiO₂ anatase thin film of about 200 m was self-assembled using the layer-by-layer ESA methodology of the present invention using a 15 m TiO₂ anatase as the nanoparticle and 3-MPS as the polyelectrolyte. A 100 nm Au film was then self-assembled on the TiO₂ layer by the NISA method of the present invention using HAuCl₄ as the gold source and NaHB₄ as the reduction agent. A monolayer of bi-functional thiol molecules was used to modify the surface of the Au film to enhance the up taking of the InP Q-dots which had a thickness of about 80 nm.

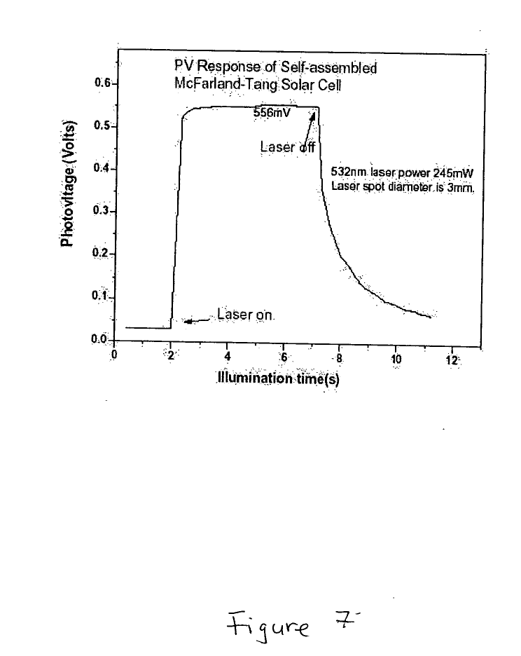

A solar simulator was used as the light source to illuminate the device from the InP Q-dot film side. FIG. 7 illustrates that this InP Q-dot sensitized Au/TiO₂/Ti solar cell exhibited a good photovoltaic (PV) response under 532 m light illuminated by a laser powered at 245 mW.

Various modifications and variations of the described methods and systems of the present invention will be apparent to those skilled in the art without departing from the scope and spirit of the invention. Although the invention has been described in connection with specific embodiments, it should be understood that the invention as claimed should not be unduly limited to such specific embodiments, but only limited by the following claims herein.

1. A method of fabricating a McFarland-Tang photovoltaic device comprising:
providing an electrode layer on a substrate; and
depositing a wide bandgap semiconductor layer by self-assembly onto said electrode layer, wherein said electrode layer is positioned between said wide bandgap semiconductor layer and said substrate.

2. The method of claim 1 further comprising depositing a noble metal layer by self-assembly onto said wide bandgap layer, wherein said wide bandgap layer is positioned between said noble metal layer and said electrode layer.

3. The method of claim 2 further comprising depositing a photosensitizing layer by self-assembly onto said noble metal layer, wherein said noble metal layer is positioned between said photosensitizing layer and said wide bandgap semiconductor layer.

4. The method of claim 1, wherein said electrode layer comprises one or more metals selected from the group consisting of indium-tin-oxide, Pt, Pd, Au, and Ag.

5. The method of claim 1, wherein said wide bandgap layer comprises one or more wide bandgap n-type semiconductors selected from the group consisting of TiO₂, SnO₂, WO₃, ZnO, Nb₂O₅, and Ta₂O₃.

6. The method of claim 2, wherein said noble metal layer comprises one or more metals selected from the group consisting of Pt, Au, Pd, Ag, and Ru.

7. The method of claim 3, wherein said photosensitizing layer comprises sensitizing one or more semiconductor quantum dots prepared from the group consisting of IIB, VIA, and VA.

8. The method of claim 3, wherein said photosensitizing layer comprises one or more sensitizing Q-dots selected from the group consisting of PbS, ZnS, CdS, CdSe, CdTe, HgTe, HgSe, PbSe, InAs, InP, GaAs, InSb, InAsP, and GaASP.

9. The method of claim 1, wherein said self-assembly is selected from the group consisting of electrostatic self-assembly, layer-by-layer covalent self assembly, and nuclear induced self-assembly.

10. The method of claim 2, wherein said self-assembly is selected from the group consisting of electrostatic self-assembly, layer-by-layer covalent self assembly, and nuclear induced self-assembly.

11. The method of claim 3, wherein said self-assembly is selected from the group consisting of electrostatic self-assembly, layer-by-layer covalent self assembly, and nuclear induced self-assembly.

12. A method of manufacturing a McFarland-Tang photovoltaic device comprising:
providing an electrode layer on a substrate; and
depositing a wide bandgap semiconductor layer onto said electrode layer;
depositing a noble metal layer onto said wide bandgap semiconductor layer; and
depositing a photosensitizing layer onto said noble metal layer, wherein at least one of said layers is fabricated by self-assembly.

13. A McFarland-Tang photovoltaic (PV) device built on a silicon substrate comprising an electrode, a wide bandgap layer, a noble metal layer, and a photosensitizing layer wherein at least of said wide bandgap layer, said noble metal layer and said photosensitizing layer is fabricated by self-assembly.

14. The McFarland-Tang PV device of claim 13, wherein said wide bandgap layer has a thickness in the range of about 5 nm to about 1000 nm.

15. The McFarland-Tang PV device of claim 13, wherein said noble metal layer has a thickness in the range of about 10 nm to about 250 nm.

16. The McFarland-Tang PV device of claim 13, wherein said photosensitizing layer has a thickness in the range of about 1 nm to about 1000 nm.

17. The McFarland-Tang PV device of claim 16, wherein said photosensitizing layer has a thickness in the range of about 1 nm to about 500 nm.

18. The McFarland-Tang PV device of claim 13, wherein said photosensitizing layer comprises an InP Q-dot and has a thickness of about 80 nm.

19. The McFarland-Tang PV device of claim 13, wherein said noble metal layer comprises gold and has a thickness of about 100 nm.

20. The McFarland-Tang PV device of claim 13, wherein said wide bandgap semiconductor layer comprises TiO₂ and has a thickness of about 200 nm.

21. A McFarland-Tang PV device comprising an InP Q-dot layer having a thickness of about 80 nm, a gold layer having a thickness of about 100 nm, and a TiO₂ layer having a thickness of about 200 nm, wherein at least one of said layers is fabricated by self-assembly.

22. A McFarland-Tang PV device comprising an InP Q-dot layer having a thickness of about 80 nm, a gold layer having a thickness of about 30 nm, and a TiO₂ layer having a thickness of about 100 nm, wherein at least one of said layers is fabricated by self-assembly.
